(19) United States
(12) Patent Application Publication
(10) Pub. No.: US 2024/0196584 A1
(43) Pub. Date: Jun. 13, 2024

(54) PART COMPRISING ON ITS SURFACE A FILM INCORPORATING AT LEAST ONE PRINTED ELECTRONIC CIRCUIT PROVIDED WITH CONNECTION TERMINALS, METHOD FOR REPAIRING SUCH A PART AND PART THUS REPAIRED

(71) Applicants: Airbus SAS, BLAGNAC (FR); Airbus Defence and Space GmbH, TAUFKIRCHEN (DE)

(72) Inventors: Alois FRIEDBERGER, TAUFKIRCHEN (DE); Patrice LEFEBURE, BLAGNAC (FR); Caroline PETIOT, BLAGNAC (FR)

(21) Appl. No.: 18/530,278

(22) Filed: Dec. 6, 2023

(30) Foreign Application Priority Data
Dec. 8, 2022 (FR) 2212937

(51) Int. Cl. H05K 13/04; H05K 1/02; H05K 13/08

(52) U.S. Cl. CPC H05K 13/0486; H05K 1/0292; H05K 13/083; H05K 2201/09418

(57) ABSTRACT

A part comprising a body and a film bonded to a surface of the body and incorporating an electronic circuit. This electronic circuit comprises at least one electronic component, conductive lines connected to the electronic component and at least two connection terminals positioned on at least one of the conductive lines, each connection terminal having a cross-section, in a plane parallel to the surface of the body, greater than twice the cross-section of a conductive line. By virtue of the connection terminals, which are distributed over the electronic circuit, it is possible to replace a faulty circuit segment with a repair circuit segment.

### CROSS-REFERENCES TO RELATED APPLICATIONS

This application claims the benefit of the French patent application No. 2212937 filed on Dec. 8, 2022, the entire disclosures of which are incorporated herein by way of reference.

### FIELD OF THE INVENTION

The present patent application relates to a part comprising on its surface a film incorporating at least one printed electronic circuit provided with connection terminals, to a method for repairing such a part and to a part thus repaired.

### BACKGROUND OF THE INVENTION

According to one embodiment shown in FIGS. 1 and 2, a part 10 comprises a body 12 made of composite material and a film 14 that is bonded to the surface S12 of the body 12, and that incorporates at least one electronic circuit 16. The film 14 comprises a carrier layer 18 bonded to the surface S12 of the body 12, the electronic circuit 16 printed on the carrier layer 18 and a protective layer 20 covering the carrier layer 18 and the electronic circuit 16.

In one configuration, the electronic circuit 16 comprises at least one electronic component 22, such as a temperature sensor or pressure sensor, inter alia, and conductive lines 24 forming a network of conductive elements. As illustrated in FIG. 1, each conductive line 24 has the smallest possible cross-section. In one arrangement, a plurality of conductive lines 24 may be positioned beside one another with a small spacing between one and the next. The conductive lines 24 are printed on the carrier layer 18 by screen printing, for example.

The part 10 may be produced using plastronic techniques.

Even though the protective layer 20 allows the electronic circuit 16 to be protected, under certain circumstances, the electronic circuit 16 may be damaged and certain functionalities may no longer work.

In such circumstances, one solution consists in replacing the part 10 with a new part that is not damaged.

This solution is not optimal because it may be expensive due to the high price of the part 10 and in any case leads to waste (the changed part) that must be processed. In addition, in certain applications, such a change is not possible or difficult to envision.

### SUMMARY OF THE INVENTION

The present invention aims to remedy all or some of the drawbacks of the prior art.

To this end, one subject of the invention is a part comprising a body having a surface and a film bonded to the surface of the body and incorporating an electronic circuit, the latter having a map and comprising at least one electronic component and conductive lines connected to the electronic component, each conductive line having a first cross-section in a plane parallel to the surface of the body.

According to the invention, the electronic circuit comprises at least two connection terminals positioned on at least one of the conductive lines and in at least one connection zone, each connection terminal having a second cross-section, in a plane parallel to the surface of the body, greater than twice the first cross-section of a conductive line. In addition, the connection zone intersects with a plurality of conductive lines and comprises for each thereof one connection terminal, the connection terminals being spaced further apart than the conductive lines so as to be able to interact with a connection system of a repair circuit segment.

By virtue of the connection terminals, it is possible to replace a faulty circuit segment with a repair circuit segment. Thus, a part comprising on its surface a film incorporating a printed electronic circuit may be repaired without having to be completely changed.

According to another feature, the electronic circuit comprises a plurality of connection zones, each comprising at least one connection terminal, these being distributed over the electronic circuit and allowing circuit segments to be isolated from one another.

Another subject of the invention is a method for repairing a part according to one of the preceding features. This method comprises a step of detecting and/or locating a fault, a step of identifying, for each detected fault, a faulty circuit segment incorporating the detected fault and, knowing the map of the electronic circuit, first and second connection terminals of each identified faulty circuit segment and, for each identified faulty circuit segment, a step of installing a repair circuit segment connected to the first and second connection terminals located at the ends of the identified faulty circuit segment, each repair circuit segment comprising at its ends first and second connection systems configured to interact with the first and second connection terminals.

According to another feature, the method comprises a step of removing one portion of a protective layer covering each of the identified first and second connection terminals.

According to another feature, the step of installing each repair circuit segment comprises using a repair module that comprises a carrier bearing the repair circuit segment and the first and second connection systems, and in connecting the first and second connection systems of the repair module to the first and second connection terminals.

According to another feature, the carrier of the repair module is a textile strip, the repair circuit segment comprising flexible conductive wires incorporated into the textile strip.

According to another feature, the repair module comprises at least one heating system.

According to another feature, the heating system is a metal sheet covering the repair circuit segment.

Lastly, another subject of the invention is a part repaired using the repairing method according to one of the above features.

### BRIEF DESCRIPTION OF THE DRAWINGS

Further features and advantages will become apparent from the following description of the invention, which description is given solely by way of example, with reference to the appended drawings, in which:

FIG. 1 is a perspective view of a part comprising on its surface a film incorporating a printed electronic circuit illustrating one embodiment of the prior art,

FIG. 2 is a section of the part shown in FIG. 1,

FIG. 3 is a top view of a part comprising on its surface a film incorporating a printed electronic circuit and connection zones illustrating one embodiment of the invention,

FIG. 4 is a section along line IV-IV in FIG. 3 of a part comprising on its surface a film incorporating a printed electronic circuit and connection zones illustrating one embodiment of the invention,

FIG. 5 is a section of the part shown in FIG. 4 after a step of removing one portion of a protective layer plumb with the connection zones illustrating one embodiment of the invention,

FIG. 6 is a section of the part shown in FIG. 5 after a step of installing a repair circuit segment illustrating one embodiment of the invention,

FIG. 7 is a perspective view of a part comprising a repair circuit segment illustrating a first configuration of the invention,

FIG. 8 is a perspective view of a part comprising two repair circuit segments illustrating another configuration of the invention,

FIG. 9 is a section of a connection zone illustrating one embodiment of the invention,

FIG. 10 is a section of a connection zone illustrating another embodiment of the invention,

FIG. 11 is a perspective view of a repair module illustrating one embodiment of the invention,

FIG. 12 is a schematic representation of one portion of an electronic circuit illustrating a first arrangement of the invention, and

FIG. 13 is a schematic representation of one portion of an electronic circuit illustrating another arrangement of the invention.

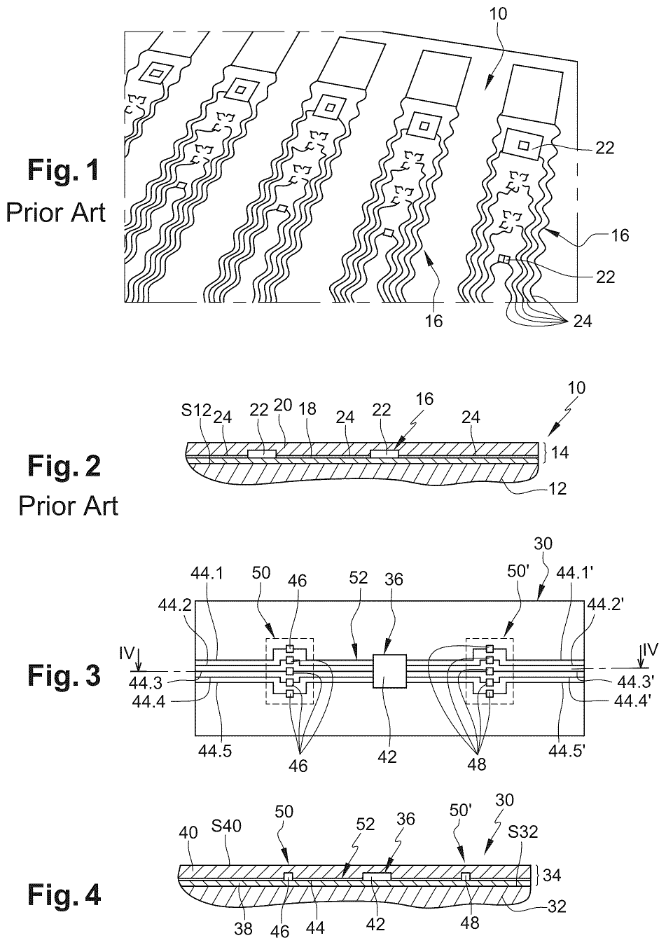

### DETAILED DESCRIPTION OF THE PREFERRED EMBODIMENTS

According to one embodiment shown in FIGS. 3 and 4, a part 30 comprises a body 32 with a surface S32, and a film 34 that is bonded to the surface S32 of the body 32 and that incorporates at least one electronic circuit 36.

In one configuration, the body 32 is made of a composite material or of a plastic. The surface S32 may be planar, as illustrated in FIG. 4, or curved.

The film 34 comprises a carrier layer 38 fastened to the surface S32 of the body 32, the electronic circuit 36 bonded to the carrier layer 38 and a protective layer 40 at least partially covering the carrier layer 38 and the electronic circuit 36.

In one configuration, the electronic circuit 36 has a map and comprises at least one electronic component 42, such as a temperature or pressure sensor, inter alia, and conductive lines 44 connected to the electronic component 42 and having a first cross-section in a plane parallel to the surface S32 of the body 32. The protective layer 40 has a free surface S40 distant from the electronic components 42 and from the conductive lines 44.

As illustrated in FIG. 3, each conductive line 44 has a small first cross-section. In one arrangement, a plurality of conductive lines 44 may be positioned beside one another with a small spacing between one and the next. In one operating mode, the conductive lines 44, 44.1 to 44.5, 44.1′ to 44.5′ are printed on the carrier layer 38 by screen printing, for example.

The body 32, the carrier layer 38, the protective layer 40, the electronic components 42 and the conductive lines 44 will not be described further since they may be identical to those of the prior art.

In one application, an aircraft comprises at least one part 30, as illustrated in FIGS. 3 and 4.

According to a particularity of the invention, the electronic circuit 36 comprises at least two connection terminals 46, 48 positioned on at least one of the conductive lines 44 and in at least one connection zone 50, 50′.

In a first arrangement shown in FIG. 12, the two connection terminals 46, 48 are positioned in the same connection zone 50, a circuit segment 52 being isolated between the two connection terminals 46, 48.

In a second arrangement shown in FIG. 13, the two connection terminals 46, 48 are positioned in two separate connection zones 50, 50′, a circuit segment 52 being isolated between the two connection terminals 46, 48.

In one configuration, the electronic circuit 36 comprises a plurality of connection zones 50, 50′, each comprising at least one connection terminal 46, 48, these being distributed over the electronic circuit 36 and allowing circuit segments 52 to be isolated from one another.

According to one arrangement shown in FIG. 3, the electronic circuit 36 comprises five upstream conductive lines 44.1 to 44.5 positioned upstream of a circuit segment 52, five downstream conductive lines 44.1′ to 44.5′ positioned downstream of the circuit segment 52, a first connection zone 50 intersecting with the five upstream conductive lines 44.1 to 44.5 and comprising for each thereof one upstream connection terminal 46, and a second connection zone 50′ intersecting with the five downstream conductive lines 44.1′ to 44.5′ and comprising for each thereof one downstream connection terminal 48.

Whatever the embodiment, each connection terminal 46, 48 has a second cross-section, in a plane parallel to the surface S32 of the body 32, greater than twice the first cross-section of a conductive line 44, in order to allow a connection. This configuration makes it possible to be able to connect to the connection terminals 46, 48 an external instrument or a repair circuit segment for example. By way of indication, each connection terminal 46, 48 has, seen from above, the shape of a square with a side length greater than or equal to 1 mm, and preferably of the order of 2 mm, or of a circle with a diameter greater than or equal to 1 mm, and preferably of the order of 2 mm.

In addition, when the connection zone 50, 50′ intersects with a plurality of conductive lines and comprises for each thereof one connection terminal 46, 48, the various connection terminals 46, 48 are spaced further apart than the conductive lines 44 to facilitate connection of an external instrument or of a repair circuit segment.

According to one embodiment, the connection terminals 46, 48 have a thickness configured so that they lie flush with the free surface S40 of the protective layer. As a variant, the connection terminals 46, 48 are covered by the protective layer 40.

In operation, the electronic circuit 36 may comprise at least one fault 54 such as a break in a conductive line and/or a short-circuit, for example, as illustrated in FIG. 7.

According to one operating mode, a method for repairing the electronic circuit 36 comprises a step of detecting and/or locating the fault 54. According to a first embodiment, the electronic circuit 36 is configured to carry out a self-test in order to detect and/or locate the fault 54. According to a second embodiment, external detection and/or location equipment, separate from the electronic circuit 36, is used to detect and/or locate the fault 54. At least one connection zone 50, 50′ may be used to connect the external equipment to the electronic circuit 36 in order to carry out the detection and/or location step. To this end, the portions positioned above the connection zones 50, 50′ are removed to expose the connection terminals 46, 48 if the latter are covered by the protective layer 40.

According to the first and second embodiments, the step of detecting and/or locating the fault 54 comprises a reflectometry-based diagnostic method.

Following the detecting and/or locating step, the repair method comprises a step of identifying, for each detected fault, the circuit segment 52 incorporating the fault and, knowing the map of the electronic circuit 36, the first and second connection terminals 46, 48 of each identified circuit segment 52 and the corresponding connection zone or zones 50, 50′.

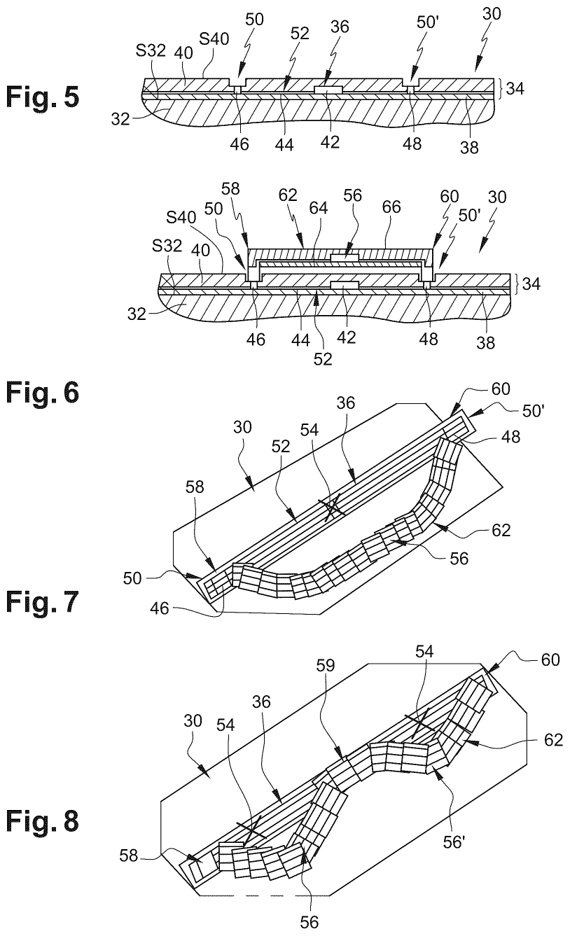

If the connection terminals 46, 48 are covered by the protective layer 40, the repair method comprises a step of removing a portion of the protective layer 40 located above each of the identified first and second connection terminals 46, 48, as illustrated in FIG. 5. According to one embodiment, a laser beam is used to effect this removal. By way of example, a portable laser source is used, in particular a laser source that preferably incorporates a pulsed diode and that emits a UV laser beam having a pulse width comprised between 1 and 100 ns. Of course, the invention is not limited to this embodiment of the laser beam. The latter is, in particular, chosen depending on the nature of the protective layer 40.

During the removing step, a system for measuring the depth of material removed, such as a spectroscopic system for example, may be used to determine when enough material has been removed to expose the first and second connection terminals 46, 48.

In one configuration, the protective layer 40 comprises at least one marking delineating at least one connection zone 50, 50′ so as to make the latter easier to find, particularly when the protective layer 40 is opaque. In one configuration, the protective layer 40 comprises one marking for each connection zone 50, 50′.

After the removing step, the repair method comprises a step of installing a repair circuit segment 56, as illustrated in FIG. 6, the repair circuit segment being connected to the first and second connection terminals 46, 48 located at the ends of the faulty circuit segment 52. In one configuration, the repair circuit segment 56 is identical to the circuit segment 52 and comprises the same electronic components 42 and the same conductive lines 44 as the faulty circuit segment 52.

The repair circuit segment 56 comprises at its ends first and second connection systems 58, 60 that are configured to interact with the first and second connection terminals 46, 48.

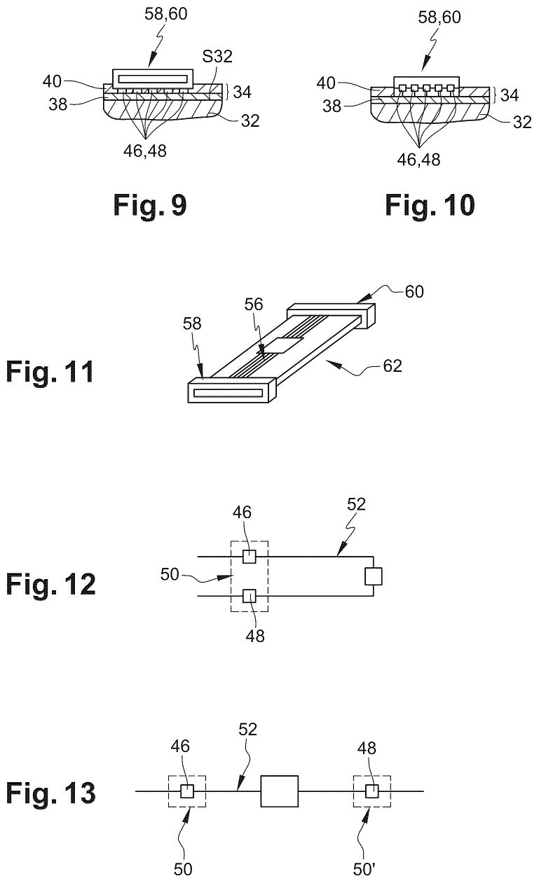

According to one embodiment shown in FIG. 9, the first and second connection systems 58, 60 are adhesively bonded to the first and second connection terminals 46, 48. As a variant, the first and second connection systems 58, 60 may be held in contact against the first and second connection terminals 46, 48 by other holding systems, for example such as clips or staples inter alia.

According to another embodiment shown in FIG. 10, the first (or second) connection terminal 46 (or 48) and the first (or second) connection system 58 (or 60) are configured to interact with each other and form the male and female portions of a connection system.

According to one embodiment, the step of installing each repair circuit segment 56 comprises using a repair module 62, comprising a carrier 64 configured to bear the repair circuit segment 56 and the first and second connection systems 58, 60, and in connecting the first and second connection systems 58, 60 of the repair module 62 to the first and second connection terminals 46, 48.

In one configuration shown in FIGS. 6 and 7, a repair module 62 comprises a single repair circuit segment 56 and two connection systems 58, 60.

In another configuration shown in FIG. 8, a repair module 62 comprises a plurality of repair circuit segments 56, 56′ each comprising two connection systems 58, 59, 60, one connection system 59 being common to the two repair circuit segments 56, 56′.

Whatever the embodiment, the repair module 62 comprises at least one repair circuit segment 56 and at least two connection systems 58, 60.

The repair module 62 may comprise a protective layer 66 covering each repair circuit segment 56, 56′.

The carrier 64 may be rigid or flexible. In one configuration, the carrier 64 takes the form of a flexible textile strip and the repair circuit segment 56 comprises flexible conductive wires incorporated into the textile strip.

In one configuration, the step of installing each repair circuit segment 56 comprises a phase of polymerizing the repair module 62. According to one embodiment, the repair module 62 is self-polymerizable and comprises at least one heating system. According to one design, the heating system is an optionally perforated metal sheet covering the repair circuit segment 56, 56′. Thus, this metal sheet performs the function of a heating element when it passes an electric current but also the function of mechanical protection, the function of protection against lightning, the function of an electrical ground layer and/or the function of a shielding layer.

According to one embodiment, the repair module 62 comprises at least one sealing system plumb with the at least one connection system 58, 60. This sealing system may comprise a material that is partially meltable at the polymerization temperature of the repair module 62 or at the bonding temperature of the connection systems 58, 60.

By virtue of the connection terminals 46, 48, which are distributed over the electronic circuit, it is possible to replace a faulty circuit segment 52 with a repair circuit segment 56. Thus, a part comprising on its surface a film incorporating a printed electronic circuit 36 may be repaired without having to be completely changed.

While at least one exemplary embodiment of the present invention(s) is disclosed herein, it should be understood that modifications, substitutions and alternatives may be apparent to one of ordinary skill in the art and can be made without departing from the scope of this disclosure. This disclosure is intended to cover any adaptations or variations of the exemplary embodiment(s). In addition, in this disclosure, the terms “comprise” or “comprising” do not exclude other elements or steps, the terms “a” or “one” do not exclude a plural number, and the term “or” means either or both. Furthermore, characteristics or steps which have been described may also be used in combination with other characteristics or steps and in any order unless the disclosure or context suggests otherwise. This disclosure hereby incorporates by reference the complete disclosure of any patent or application from which it claims benefit or priority.

1. A part comprising:
a body having a surface and
a film bonded to the surface of the body and incorporating an electronic circuit, the electronic circuit having a map and comprising at least one electronic component and conductive lines connected to the electronic component, each conductive line having a first cross-section in a plane parallel to the surface of the body;
wherein the electronic circuit comprises at least two connection terminals positioned on at least one of the conductive lines and in at least one connection zone, each connection terminal having a second cross-section, in a plane parallel to the surface of the body, greater than twice the first cross-section of a conductive line, and
wherein the at least one connection zone intersects with a plurality of conductive lines and comprises, for each thereof, one connection terminal, the connection terminals being spaced further apart than the conductive lines so as to be able to interact with a connection system of a repair circuit segment.

2. The part as claimed in claim 1, wherein the electronic circuit comprises a plurality of connection zones each comprising at least one connection terminal, these being distributed over the electronic circuit and allowing circuit segments to be isolated from one another.

3. A method for repairing a part as claimed in claim 1, wherein the method comprises:
a step of detecting and/or locating a fault,
a step of identifying, for each detected fault, a faulty circuit segment incorporating the detected fault and, knowing the map of the electronic circuit, first and second connection terminals of each identified faulty circuit segment and, for each identified faulty circuit segment,
a step of installing a repair circuit segment connected to the first and second connection terminals located at ends of the identified faulty circuit segment, each repair circuit segment comprising at ends thereof, first and second connection systems configured to interact with the first and second connection terminals.

4. The method as claimed in claim 3, further comprising a step of removing one portion of a protective layer covering each of the identified first and second connection terminals.

5. The method as claimed in claim 4, wherein the step of installing each repair circuit segment comprises using a repair module, comprising a carrier bearing the repair circuit segment and the first and second connection systems, and in connecting the first and second connection systems of the repair module to the first and second connection terminals.

6. The method as claimed in claim 5, wherein the carrier of the repair module is a textile strip, the repair circuit segment comprising flexible conductive wires incorporated into the textile strip.

7. The method as claimed in claim 5, wherein the repair module comprises at least one heating system.

8. The repair method as claimed in claim 7, wherein the heating system is a metal sheet covering the repair circuit segment.

9. A part repaired using the repair method as claimed in claim 3.
